(19) United States
(12) Patent Application Publication
(10) Pub. No.: US 2013/0093512 A1
(43) Pub. Date: Apr. 18, 2013

(54) POWER AMPLIFIER AND OPERATION CONTROLLING CIRCUIT THEREOF

(71) Applicants: Shinichi IIZUKA, Suwon (KR); Jun Kyung Na, Anyang (KR); Sang Hoon Ha, Suwon (KR); Youn Suk Kim, Yongin (KR)

(72) Inventors: Shinichi IIZUKA, Suwon (KR); Jun Kyung Na, Anyang (KR); Sang Hoon Ha, Suwon (KR); Youn Suk Kim, Yongin (KR)

(73) Assignee: SAMSUNG ELECTRO-MECHANICS CO., LTD.

(21) Appl. No.: 13/333,317

(22) Filed: Dec. 21, 2011

(30) Foreign Application Priority Data
Oct. 14, 2011 (KR) 10-2011-0105227

(51) Int. Cl. H03G 3/20

(52) U.S. Cl. 330/127

(57) ABSTRACT

There are provided a power amplifier and an operation controlling circuit thereof. The power amplifier includes: a signal generating unit generating a current input signal; an amplifying unit amplifying the current input signal; and a driving circuit unit supplying a driving signal to the amplifying unit, wherein the signal generating unit includes a control circuit unit generating a predetermined voltage signal from input power and a current mirror circuit unit generating the current input signal from the voltage signal.

### CROSS-REFERENCE TO RELATED APPLICATIONS

This application claims the priority of Korean Patent Application No. 10-2011-0105227 filed on Oct. 14, 2011, in the Korean Intellectual Property Office, the disclosure of which is incorporated herein by reference.

### BACKGROUND OF THE INVENTION

1. Field of the Invention

The present invention relates to a power amplifier generating an input signal applied to an amplifying unit separately from a power supply voltage operating the power amplifier so that a stable output signal may be obtained, even in the case in which a variation occurs in the power supply voltage, and an operation controlling circuit thereof.

2. Description of the Related Art

A power amplifier, a circuit amplifying a predetermined input signal to generate an output signal, is widely used in a power supply of an electronic device or in amplifying a communications signal of a wireless communications device. The power amplifier may include an amplifying circuit amplifying a target input signal to generate an output signal, and a bias circuit applying a bias signal for operating the amplifying circuit in a voltage or current form.

A power amplifier is generally implemented by a plurality of elements such as an operational amplifier, a transistor, a resistor, and the like, and receives power required for driving from battery voltage, power supply voltage, or the like, input to the electronic device. Here, in the case in which the battery voltage, the power supply voltage, or the like, is varied due to internal or external factors, a level of an input signal applied to the power amplifier, that is, a target signal to be amplified by the power amplifier may also be varied, such that overall power amplifier stability, particularly, power characteristics, may be deteriorated.

Particularly, in the case of a power amplifier implemented by a plurality of switching elements, a circuit generating the target input signal to be amplified by the power amplifier and a circuit generating a driving signal may be operated at the same voltage. In this case, when a variation occurs in the power supply voltage, both of a level of a driving signal output from a circuit generating the driving signal and a level of an input signal are not stabilized, but are varied, such that a large deviation in power is generated, according to a driving environment.

### SUMMARY OF THE INVENTION

An aspect of the present invention provides a power amplifier capable of obtaining stable output characteristics, even in the case of variations in power supply voltage supplied from a battery, or the like, by generating a target input signal to be amplified in an amplifying unit, separately from the power supply voltage operating the power amplifier, and an operation controlling circuit thereof.

According to an aspect of the present invention, there is provided a power amplifier including: a signal generating unit generating a current input signal; an amplifying unit amplifying the current input signal; and a driving circuit unit supplying a driving signal to the amplifying unit, wherein the signal generating unit includes a control circuit unit generating a predetermined voltage signal from input power and a current mirror circuit unit generating the current input signal from the voltage signal.

The signal generating unit may control a current level of the current input signal amplified by the amplifying unit using the current mirror circuit unit.

The driving circuit unit may include a voltage regulator circuit generating the driving signal from a predetermined first voltage.

The driving circuit unit may include a low dropout regulator circuit.

The signal generating unit may generate the current input signal separately from a variation in a first voltage applied to the driving circuit unit.

The signal generating unit may drive the control circuit unit and the current mirror circuit unit from a second voltage supplied separately from the first voltage.

The control circuit unit may further include an operational amplifier generating a bias signal.

According to another aspect of the present invention, there is provided an operation controlling circuit of a power amplifier, the operation controlling circuit including: a driving circuit unit generating a driving signal for operating an amplifying circuit from a predetermined first voltage; and a signal generating unit generating a current input signal applied to the amplifying circuit, wherein the signal generating unit is operated by receiving a second voltage generated separately from the first voltage and controls a current level of the current input signal applied to the amplifying circuit.

The signal generating unit may include a current mirror circuit unit controlling the current input signal applied to the amplifying circuit and a control circuit unit operated by the second voltage and generating a voltage signal determining current input to the current mirror circuit unit from a predetermined input voltage.

The operation controlling circuit may further include a matching filter controlling a level of the current input signal applied to the amplifying circuit.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a block diagram showing a power amplifier according to an embodiment of the present invention;

FIG. 2 is a circuit diagram provided in order to help in an understanding of an operation of a power amplifier according to an embodiment of the present invention;

FIG. 3 is a circuit diagram showing a power amplifier according to an embodiment of the present invention; and

FIG. 4 is a graph provided in order to describe an effect of a power amplifier according to an embodiment of the present invention.

### DETAILED DESCRIPTION OF THE PREFERRED EMBODIMENT

Embodiments of the present invention will be described in detail with reference to the accompanying drawings. These embodiments will be described in detail for those skilled in the art in order to practice the present invention. It should be appreciated that various embodiments of the present invention are different but are not necessarily exclusive. For example, specific shapes, configurations, and characteristics described in an embodiment of the present invention may be implemented in another embodiment without departing from the spirit and scope of the present invention. In addition, it should be understood that positions and arrangements of individual components in each disclosed embodiment may be changed without departing from the spirit and scope of the present invention. Therefore, a detailed description provided below should not be construed as being restrictive. In addition, the scope of the present invention is defined only by the accompanying claims and their equivalents if appropriate. Similar reference numerals will be used to describe the same or similar functions throughout the accompanying drawings.

Hereinafter, embodiments of the present invention will be described in detail with reference to the accompanying drawings so that those skilled in the art may easily practice the present invention.

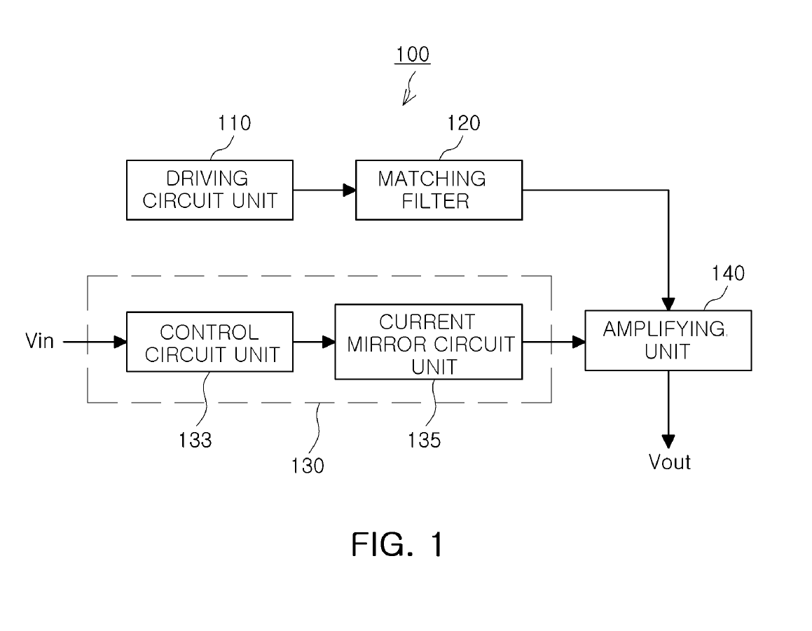

FIG. 1 is a block diagram showing a power amplifier according to an embodiment of the present invention.

Referring to FIG. 1, a power amplifier 100 according to an embodiment of the present invention may include a driving circuit unit 110, a matching filter 120, a signal generating unit 130, and an amplifying unit 140. The signal generating unit 130 may include a control circuit unit 133 and a current mirror circuit unit 135.

The driving circuit unit 110 may determine voltage input to a matching filter using voltage supplied from the outside, for example, voltage supplied from a battery, or the like, of a portable device when it is assumed that the power amplifier 100 according to the present embodiment is included in the portable device, or the like. As described below, the driving circuit unit 110 may include an operational amplifier, a switching element, and the like, and an output signal of the driving circuit unit 110 may be input to the matching filter 120. Hereinafter, although it is assumed that the driving circuit unit 110 is implemented as a low dropout regulator throughout the specification for convenience of explanation, the driving circuit unit 110 is not limited thereto, and may also be implemented as a general voltage regulator.

The matching filter 120 determines an input signal supplied to the amplifying unit 140 based on the signal output from the driving circuit unit 110. When it is assumed that the input signal is supplied in a current form to the amplifying unit 140, the matching filter 120 may include a current distributing circuit distributing current output from the driving circuit unit 110 to determine the input signal supplied to the amplifying unit 140. The matching filter 120 may be simply implemented by a plurality of resistors providing different current paths and control the input current applied to the amplifying unit 140 through ratios among the plurality of resistors.

When it is assumed that the matching filter 120 includes the plurality of resistors, the individual resistors included in the matching filter 120 may be connected in parallel with each other in order to provide different current paths. Particularly, at least one of both terminals of each resistor maybe connected to at least one of both terminals of an adjacent resistor in a common node. The node in which the plurality of resistors are connected in common may be supplied with output voltage of the driving circuit unit 110, and magnitudes of currents distributed to the individual resistors of the matching filter 120 may be determined according to the ratios among the individual resistors, the output voltage of the driving circuit unit 110, and output current of the signal generating unit 130.

The signal generating unit 130 may receive a predetermined input voltage Vᵢₙ (See FIG. 1) to determine voltage applied to an input terminal of the amplifying unit 140 and may include the control circuit unit 133 and the current mirror circuit unit 135.

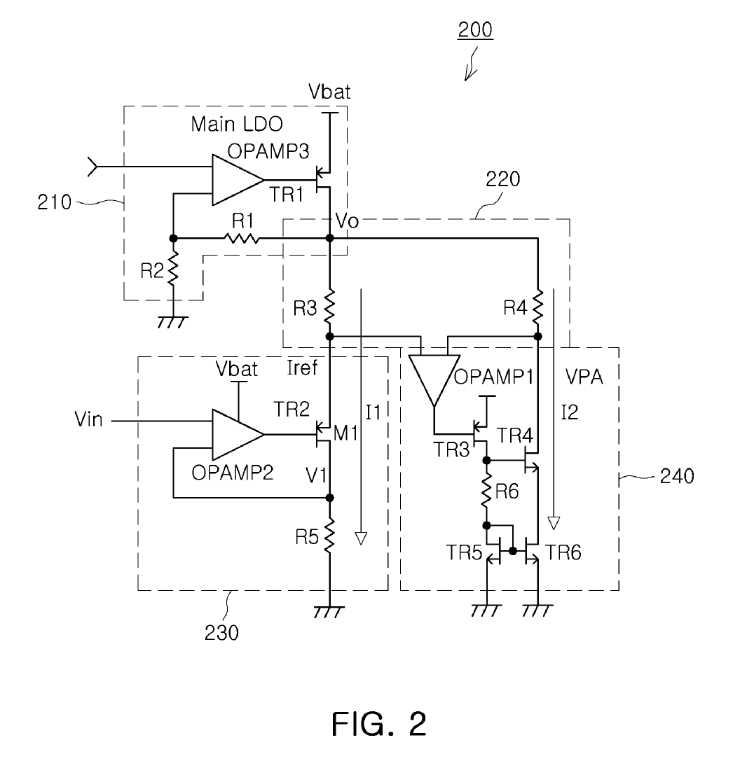

The control circuit unit 130 may include an operational amplifier, a switching element, and a resistor, and receive the predetermined input voltage to generate a bias signal applied to the current mirror circuit unit 135. For example, the control circuit unit 133 may be implemented as a voltage follower circuit using an operational amplifier, and a switching element such as a transistor connected to the current mirror circuit unit 135 may be connected to an output terminal of the voltage follower circuit. The voltage follower circuit may generate a predetermined output current determined according to the input voltage and a resistor connected to a load terminal and be configured so as to have an output current corresponding to current applied to an input terminal of the current mirror current unit 135. A detailed content thereof will be described below with reference to FIG. 2.

Although not shown in FIG. 1, the amplifying unit 140 may include a plurality of switching elements and a bias circuit applying a predetermined bias signal to at least some of the plurality of switching elements. As an example, a magnitude of the bias signal transferred from the bias circuit to the amplifying unit 140 may be determined according to output current of the current mirror circuit unit 135 and voltage applied to the input terminal of the amplifying unit 140. The bias circuit may include an operational amplifier, a switching element, a resistor, and the like. Particularly, inverting and non-inverting input terminals of the operational amplifier included in the bias circuit may be connected to the output current of the current mirror circuit unit 135 and the input terminal of the amplifying unit 140 to generate the bias signal such that the output current of the current mirror circuit unit 135 and the voltage at the input terminal of the amplifying unit 140 correspond to each other.

As seen from a connection relationship between the respective components 110 to 140 shown in FIG. 1, a driving signal required for operating the amplifying unit 140 may be transferred from the driving circuit unit 110 through the matching filter 120, and the driving circuit unit 110 may generate the driving signal from a predetermined power supply voltage (a battery voltage Vbat in the case of a mobile device). In addition, a bias signal for a plurality of amplifying elements, for example, transistors, included in the amplifying unit 140 may be supplied from the signal generating unit 130. Therefore, when it is assumed that the signal generating unit 130 is operated by the same power supply voltage Vbat as that of the driving circuit unit 110 in a general circuit configuration, signals respectively output from the signal generating unit 130 and the driving circuit unit 110 may be varied according to a variation in the power supply voltage Vbat, such that output may be unstable.

The unintended variation in the output as described above may be generated, since the variation in the power supply voltage Vbat may cause a variation in a voltage level at another node determining a magnitude of current input to the amplifying unit 140, and may be significantly high, particularly in a low power mode. Furthermore, when it is assumed that the power supply voltage Vbat is supplied from a battery, such as a mobile device, or the like, in the case in which Vbat is varied in a range of 3.0 to 4.5V, a deviation in Vbat appears as a deviation in output as it is. Therefore, a need exists for a method capable of securing a stable output by covering a variation range in the power supply voltage Vbat as widely as possible.

As described above, the deviation in the output according to the variation in the power supply voltage Vbat may be generated since the signal generating unit 130 determining a target input signal to be amplified by the amplifying unit 140 is operated by the same power supply voltage Vbat as that of the driving circuit unit 110. For example, when the signal generating unit 130 is formed as the voltage follower circuit and includes at least one operational amplifier, the operational amplifier may be operated by the power supply voltage Vbat. In this case, the variation in the power supply voltage Vbat may cause a variation in output of the operational amplifier, which may be reflected in the input signal of the amplifying unit 140 to cause a deviation in power output by the amplifying unit 140.

Therefore, in order to significantly reduce the deviation in the output according to the variation in the power supply voltage Vbat, a driving voltage Vreg for operating the signal generating unit 130 may be applied from a power supply separate from the power supply voltage Vbat. In addition, the signal generating unit 130 includes the control circuit unit 133 and the current mirror circuit unit 135, such that a signal generated by the control circuit unit 133 from the driving voltage Vreg is applied to the amplifying unit 140 through the current mirror circuit unit 135 without being applied directly to the amplifying unit 140. The current input to the current mirror circuit unit 135 maybe determined from a voltage signal generated by the control circuit unit 133 and the current mirror circuit unit 135 may control a target input signal to be amplified by the amplifying unit 140 therefrom in a current form, which will be described with reference to FIG. 2. Therefore, a circuit less affected by the variation in the power supply voltage Vbat as compared to the case of the voltage control may be provided.

FIG. 2 is a circuit diagram provided in order to help in an understanding of an operation of a power amplifier according to an embodiment of the present invention. Referring to FIG. 2, a power amplifier 200 may include a driving circuit unit 210, a matching filter 220, a signal generating unit 230, and an amplifying unit 240. It is to be noted that although a detailed circuit of each component included in the power amplifier 200 is shown in FIG. 2, this is only an example.

Referring to FIG. 2, the driving circuit unit 210 may be implemented as a voltage regulator circuit such as a low dropout regulator and include a transistor TR1, which is a switching element, and an operational amplifier OP-AMP3. The operational amplifier OP-AMP3 may have a voltage Vd applied to any input terminal thereof in order to generate a driving voltage of the power amplifier 200 and have an output terminal connected to a gate of the transistor TR1. An output voltage Vo of the driving circuit unit 210 corresponding to a drain voltage of the transistor TR1 may be determined by a source voltage Vbat of the transistor TR1 and the voltage Vd applied to the input terminal of the operational amplifier OP-AMP3. Here, Vbat refers to a power supply voltage supplied from a power supply unit such as a battery, or the like, as described above with reference to FIG. 1.

The signal generating unit 230 connected to an output terminal of the driving circuit unit 210 through a resistor R₃ of the matching filter 220 may be implemented as an operational amplifier OP-AMP2 and a transistor TR2, similar to the driving circuit unit 210. However, a circuit is implemented such that a drain voltage V₁ of the transistor TR2 has the same level as an input voltage Vᵢₙ of the signal generating unit 240 by directly connecting a drain of the transistor TR2 to any input terminal of the operational amplifier OP-AMP2. As a result, current flowing in the drain of the transistor TR2 may be determined by the drain voltage V₁ and a resistor R₅. In addition, since current I₁ introduced from a source terminal of the transistor TR 2 has the same level as the current flowing in the drain of the transistor TR2 in view of the characteristics of a transistor, current I₁ may also be determined by the drain voltage V₁ and the resistor R₅.

A target signal to be amplified by the amplifying unit 240 may be applied in a current form and may be represented by I₂ in FIG. 2. Since the matching filter 220 is configured of resistors R₃ and R₄ and resistance of an input terminal is significantly large (ideally infinite) in view of the characteristics of an operational amplifier OP-AMP1, the magnitudes of voltages across the resistors R₃ and R₄ are the same. Therefore, a magnitude of the current input signal I₂ applied to the amplifying unit 240 may be determined by a ratio between resistance values of the resistors R₃ and R₄. As an example, when the resistors R₃ and R₄ have respective resistance values of 50Ω and 50 Ωm, the currents Iₗ and I₂ may be divided in the ratio of 1:1000. When the current I₂ is determined, a voltage V_{PA} in an input terminal of the amplifying unit 240 may be determined accordingly.

The amplifying unit 240 may include a plurality of amplifying elements (transistors TR4 and TR6 in FIG. 2) amplifying the current input signal I₂ and a bias circuit applying a predetermined bias signal to the plurality of amplifying elements. Referring to FIG. 2, the bias circuit may be implemented by the operational amplifier OP-AMP1, the transistors TR3 and TR5, and the resistor R₆, and a predetermined voltage Vdd may be applied to a source terminal of the transistor TR3. When the transistor TR3 is conducted by applying a voltage having a predetermined level or greater to a gate terminal of the transistor TR3 connected to an output terminal of the operational amplifier OP-AMP1, the voltage Vdd applied to the source terminal of the transistor TR3 is applied as a bias signal to each of the transistors TR4 and TR6.

As shown in FIG. 2, an input signal applied to the amplifying unit 240 through the matching filter 220 may be represented by the current input signal I₂ or the voltage V_{PA}, and may be determined by the output voltage Vo of the driving circuit unit 210 and the output voltage V₁ of the signal generating unit 230 or the output voltage V₁ and the current I₁ by the resistor R₅. In addition, since the output voltage Vo of the driving circuit unit 210 is determined by the power supply voltage Vbat applied to the source terminal of the transistor TR1 and the output voltage V₁ of the signal generating unit 230 is also affected by the power supply voltage Vbat applied in order to drive the operational amplifier OP-AMP2, a variation in the power supply voltage Vbat affects the current I₁ and also affects the current input signal I₂ of the amplifying unit 240, thereby causing the output of the amplifying unit 240 to be unstable.

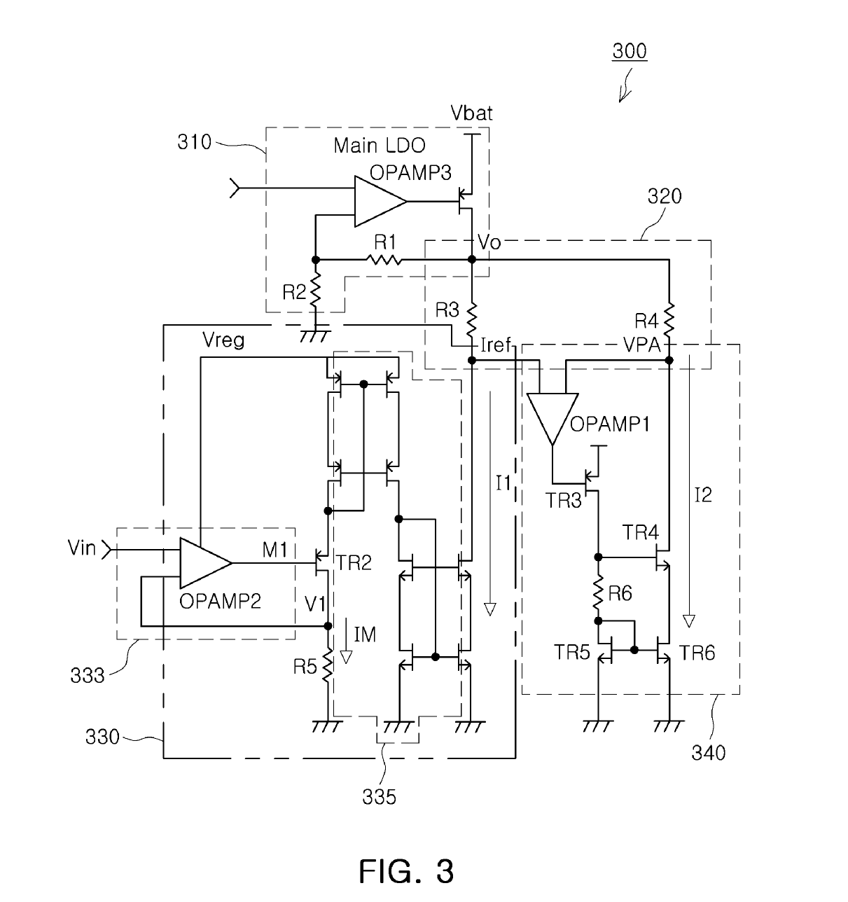

In order to prevent the output thereof from being unstable, a current mirror circuit unit may be added in the signal generating unit 230. Hereinafter, a detailed description will be provided with reference to FIG. 3.

FIG. 3 is a circuit diagram showing a power amplifier according to an embodiment of the present invention. Referring to FIG. 3, a power amplifier 300 includes a driving circuit unit 310, a matching filter 320, a signal generating unit 330, and an amplifying unit 340, similar to FIG. 2. However, the signal generating unit 330 includes a control circuit unit 333 implemented as a voltage follower and a current mirror circuit unit 335, unlike FIG. 2. That is, unlike FIG. 2, current I₁ determined by output voltage V₁ of the control circuit unit 333 implemented as the voltage follower and a resistor R₅ does not directly determine a current input signal I₂ of the amplifying unit 340, and current IM generated by current I₁ in the current mirror circuit unit 335 may determine the current input signal I₂ applied to the amplifying unit 340.

Meanwhile, voltage for driving an operational amplifier OP-AMP2 of the control circuit unit 333 included in the signal generating unit 330 and voltage Vreg for operating the current mirror circuit unit 335 may be determined separately from power supply voltage Vbat applied to the driving circuit unit 310. That is, the control circuit unit 333 and the current mirror circuit unit 335 are operated by the voltage Vreg, unrelated to a variation in the power supply voltage Vbat, whereby an output deviation according to the variation in the power supply voltage Vbat may be more effectively suppressed. As an example, Vreg may be maintained as a fixed voltage of 3.0V.

The operational amplifier OP-AMP2 operated by the voltage Vreg may output voltage applied to a gate terminal of a transistor TR2 from input voltage Vᵢₙ. When the transistor TR2 is conducted by an output of the operational amplifier OP-AMP2, current I₁ may be determined by a voltage V₁ and a resistor R₅. Output current IM of the current mirror circuit unit 335 may be determined from the current I₁, and the current input signal I₂ may be applied from the current mirror circuit unit 335 to the amplifying unit 340. Therefore, the current mirror circuit unit 335 may be disposed between the voltage V₁ of the current circuit unit 333 and the current IM determining the input current signal of the amplifying unit 340 or current I_{REF} in a node connected to an input terminal of an operational amplifier OP-AMP1, such that even in the case in which a voltage variation occurs, an influence of the voltage variation on the current IM is significantly reduced, whereby the output of the amplifying unit 340 may be stabilized.

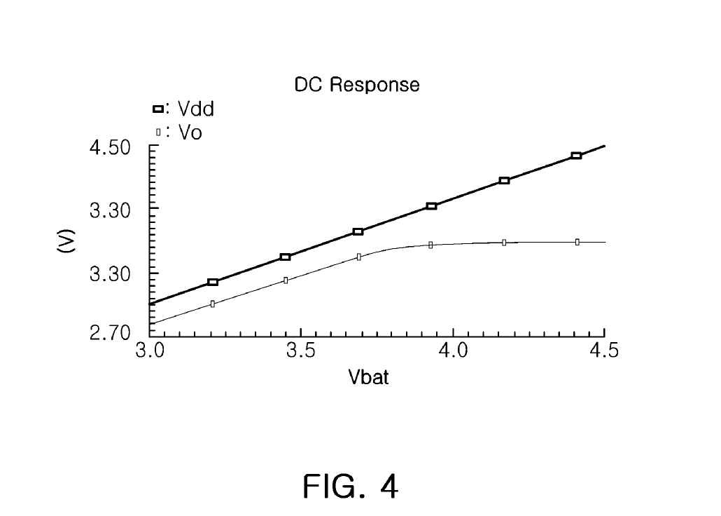

FIG. 4 is a graph provided in order to describe an effect of the power amplifier according to the embodiment of the present invention. Referring to FIG. 4, as the power supply voltage Vbat increases, the voltage Vo of the drain terminal of the transistor TR1 also increases. Then, when the power supply voltage Vbat increases to 4.0V or more, an increase rate of the voltage Vo at the drain terminal of the transistor TR1 slows down, such that the voltage Vo in the drain terminal of the transistor TR1 is saturated as a predetermined value. Therefore, a deviation between the power supply voltage Vbat and the voltage Vo at the drain terminal of the transistor TR1 (simultaneously, voltage in a node corresponding to the input terminal of the matching filter 320) is generated, such that output may be unstable particularly in a low power mode.

In the power amplifier 300 shown in FIG. 3, the voltage V₁ may be generated in the control circuit unit 333 from the voltage Vreg, different from the power supply voltage Vbat, and the current IM output from the current mirror circuit unit 335 not to be affected by the power supply voltage Vbat may determine the current input signal I₂ applied to the amplifying unit 340. Therefore, even in the case in which the voltage Vo is varied due to the variation in the power supply voltage Vbat, the voltage V₁ determining the current flowing in the current mirror circuit unit 335 is determined from the voltage Vreg, such that it may not be affected by the variation in the power supply voltage Vbat.

In addition, as described above, since the current I₁ is determined by the voltage V₁ and the resistor R₅, the current IM output through the current mirror circuit unit 335 is determined therefrom, and the current input signal I₂ applied to the amplifying unit 340 is controlled by the ratio between the resistance values of the resistors R₃ and R₄ included in the matching filter 320 and the current IM, the signals output through the amplifying elements TR4 and TR6 of the amplifying unit 340 may not be affected by the variation in the power supply voltage Vbat. As a result, in spite of the variation in the power supply voltage Vbat, a stabilized output maybe obtained.

As set forth above, according to the embodiments of the present invention, a power amplifier capable of obtaining stable output characteristics in spite of variations in power supply voltage supplied from a battery, or the like, by generating a target input signal to be amplified in an amplifying unit separately from the power supply voltage operating the power amplifier, and an operation controlling circuit thereof may be provided.

Although the present invention has been described with reference to specific embodiments, these specific embodiments are only examples and do not limit the scope of the present invention. It may be appreciated by those skilled in the art that the described embodiments may be modified or altered without departing from the scope of the present invention. The respective functional blocks or units described in the present specification maybe implemented by various known elements such as electrical circuits, integrated circuits, application specific integrated circuits (ASIC), or the like, and be implemented separately or in a combination thereof. Components such as units, or the like, described as being implemented separately in the present specification and the claims may be physically implemented as a single unit, and a component such as a unit, or the like, described as being implemented as a signal unit may also be implemented by a combination of several components. In addition, the respective method operations described in the present specification may be practiced in a changed order without departing from the scope of the present invention, and other operations may be added. Furthermore, the various embodiments described in the present specification may be implemented independently or in an appropriate combination thereof. Therefore, the scope of the present invention is to be defined by the accompanying claims and their equivalences rather than the embodiments described above.

What is claimed is:

1. A power amplifier comprising:
a signal generating unit generating a current input signal;
an amplifying unit amplifying the current input signal; and
a driving circuit unit supplying a driving signal to the amplifying unit,
wherein the signal generating unit includes a control circuit unit generating a predetermined voltage signal from input power and a current mirror circuit unit generating the current input signal from the voltage signal.

2. The power amplifier of claim 1, wherein the signal generating unit controls a current level of the current input signal to be amplified by the amplifying unit using the current mirror circuit unit.

3. The power amplifier of claim 1, wherein the driving circuit unit includes a voltage regulator circuit generating the driving signal from a predetermined first voltage.

4. The power amplifier of claim 3, wherein the driving circuit unit includes a low dropout regulator circuit.

5. The power amplifier of claim 3, wherein the signal generating unit generates the current input signal separately from a variation in a first voltage applied to the driving circuit unit.

6. The power amplifier of claim 5, wherein the signal generating unit drives the control circuit unit and the current mirror circuit unit from a second voltage supplied separately from the first voltage.

7. The power amplifier of claim 1, wherein the control circuit unit further includes an operational amplifier generating a bias signal.

8. An operation controlling circuit of a power amplifier, the operation controlling circuit comprising:
a driving circuit unit generating a driving signal for operating an amplifying circuit from a predetermined first voltage; and
a signal generating unit generating a current input signal applied to the amplifying circuit,
wherein the signal generating unit is operated by receiving a second voltage generated separately from the first voltage and controls a current level of the current input signal applied to the amplifying circuit.

9. The operation controlling circuit of claim 8, wherein the signal generating unit includes:
a current mirror circuit unit controlling the current input signal applied to the amplifying circuit; and
a control circuit unit operated by the second voltage and generating a voltage signal determining current input to the current mirror circuit unit from a predetermined input voltage.

10. The operation controlling circuit of claim 8, further comprising a matching filter controlling a level of the current input signal applied to the amplifying circuit.
